(19) United States
(12) Patent Application Publication
(10) Pub. No.: US 2023/0320027 A1
(43) Pub. Date: Oct. 5, 2023

(54) CABINET AND HEAT DISSIPATION DOOR THEREOF

(71) Applicant: KENMEC MECHANICAL ENGINEERING CO., LTD., Taipei City (TW)

(72) Inventors: Ching-Fu HSIEH, Taipei City (TW); Shih-Chen CHANG, Taipei City (TW)

(73) Assignee: KENMEC MECHANICAL ENGINEERING CO., LTD., Taipei City (TW)

(21) Appl. No.: 17/824,934

(22) Filed: May 26, 2022

Related U.S. Application Data
(60) Provisional application No. 63/320,690, filed on Mar. 16, 2022.

(30) Foreign Application Priority Data
Apr. 13, 2022 (TW) 111114124

(51) Int. Cl. H05K 7/20

(52) U.S. Cl. CPC H05K 7/20263; H05K 7/20272; H05K 7/20781

(57) ABSTRACT

A cabinet and a heat dissipation door thereof are provided. The heat dissipation door is disposed on a cabinet body and includes a first plate, a plurality of heat dissipation sheets, and a heat dissipation tube component. A plurality of heat dissipation sheets is disposed on the first plate. The heat dissipation tube component is disposed on the first plate and includes a water inlet, a water outlet, and a plurality of heat dissipation tubes. Two ends of each of the plurality of heat dissipation tubes respectively are in fluid communication with the water inlet and the water outlet, and the plurality of heat dissipation tubes has a plurality of extending sections and at least one connecting section. The plurality of extending sections passes through the plurality of heat dissipation surfaces in sequence. At least one connecting section is connected to ends of two adjacent extending sections.

### CROSS REFERENCE TO RELATED DISCLOSURE

This application claims the priority benefit of U.S. Provisional Application No. 63/320,690, filed on Mar. 16, 2022, and TW Patent Application Number 111114124, filed on Apr. 13, 2022, the full disclosure of which is incorporated herein by reference.

### BACKGROUND

### Technical Field

The present disclosure is related to a cabinet and a heat dissipation door thereof, and in particular, to a heat dissipation door that may effectively dissipate heat and is applied to a cabinet.

### Related Art

In order to provide users with more convenient services, the number of central processing unit (CPU) disposed in the server is increasing, or at least the computing ability thereof is getting better and better. In addition, the number and/or performance of components such as a graphics processing unit (GPU), a hard disk, a power supply, a memory, etc. in the server is also increasing day by day. However, the increase in the number of components and/or the increase in performance also results in a large amount of waste heat. In order to allow the servers installed in the cabinets to be in a normal working environment, a water cooling system is generally used today to quickly remove the heat generated by the servers during operation. For example, a part of the water cooling system is located in the cabinet’s heat dissipation door to exchange heat with the central processing unit of the server. However, the current water cooling system only exchanges heat with the central processing unit through the cold water pipeline disposed in the heat dissipation door. The contact area therebetween is small, resulting in low heat exchange efficiency. In addition, one path cold water pipeline also causes the heat exchange carrier (ie, the fluid in the pipeline) to absorb a large amount of heat at the position close to the water inlet so as to increase the temperature rapidly. Therefore, the function of absorbing heat at the position close to the water outlet is difficult due to insufficient temperature differences by the rapid increase of temperature. As a result, the cooling process of the entire cabinet is not stable, and a a significant temperature gradient is produced. Therefore, how to provide a heat dissipation door that can reduce the temperature difference of the cabinet and has excellent heat dissipation efficiency has become an urgent issue to be solved in the art.

### SUMMARY

The embodiments of the present disclosure disclose a cabinet and a heat dissipation door thereof, in order to solve the problem that the current cabinet is difficult to effectively dissipate heat and a obivious temperature gradient exists.

In order to solve the above technical problems, the present disclosure is implemented as follows.

In a first aspect, a heat dissipation door of cabinet is provided. The heat dissipation door of cabinet is disposed on a cabinet body and includes a first plate, a plurality of heat dissipation sheets, and a heat dissipation tube component. The plurality of heat dissipation sheets is disposed on one side of the first plate adjacent to the cabinet body, wherein each of the plurality of heat dissipation sheets has a heat dissipation surface. The heat dissipation tube component is disposed on one side of the first plate adjacent to the cabinet body and includes a water inlet, a water outlet, and a plurality of heat dissipation tubes. One end of the water inlet is in fluid communication with a heat dissipation system. One end of the water outlet is in fluid communication with the heat dissipation system. Two ends of each of the plurality of heat dissipation tubes respectively are in fluid communication with the water inlet and the water outlet. Each of the plurality of heat dissipation tubes has a plurality of extending sections and at least one connecting section. The plurality of extending sections passes through the heat dissipation surfaces in sequence, and at least one connecting section is connected to ends on the same side of two adjacent extending sections.

In some embodiments, the dissipation surfaces are orthogonal to the plurality of extending sections.

In some embodiments, the plurality of heat dissipation sheets are in direct contact with the plurality of heat dissipation tubes.

In some embodiments, the plurality of heat dissipation tubes are disposed on the first plate in a vertical direction in sequence.

In some embodiments, the water outlet and the water inlet are on a side of the first plate adjacent to a ground or on a side away from the ground.

In some embodiments, the heat dissipation door of cabinet further includes a plurality of fans disposed between the plurality of heat dissipation sheets and the cabinet body or outside the first plate, and the plurality of fans correspond to the plurality of heat dissipation sheets.

In some embodiments, the heat dissipation door of cabinet further includes a roller, wherein the roller is disposed on a side of the first plate adjacent to a ground.

In some embodiments, the heat dissipation door of cabinet further includes a second plate body, wherein the second plate body is between the cabinet body and the first plate. An accommodating space is formed between the second plate body and the first plate, and the plurality of heat dissipation tubes and the plurality of heat dissipation sheets are in the accommodating space.

In some embodiments, the first plate and the second plate respectively have a plurality of air holes.

In a second aspect, a cabinet is provided. The cabinet includes a cabinet body and the heat dissipation door according to the first aspect, wherein the heat dissipation door is disposed on the cabinet body.

In the present disclosure, by passing the heat dissipation tubes of the heat dissipation tube component through the plurality of heat dissipation sheets in sequence, the present disclosure changes the heat dissipation path from the existing “central processing unit (CPU) is directly connected to the heat dissipation tubes” to “the central processing unit (CPU) is connected to the heat dissipation tubes through the plurality of heat dissipation sheets.” As a result, the heat dissipation area may be greatly increased by the plurality of heat dissipation sheets, thereby obtaining an excellent heat dissipation effect. In addition, due to the provision of the plurality of heat dissipation tubes, the entire heat dissipation door may be divided into a plurality of sections performing heat exchange with the corresponding central processing unit (CPU). As a result, the problem that the one path cold water pipeline in the prior art has a significant temperature gradient is also solved. Based on the configuration mentioned above, a heat dissipation door of cabinet with an excellent heat dissipation effect and no significant temperature gradient is achieved by the present disclosure.

### BRIEF DESCRIPTION OF THE DRAWINGS

The figures described herein are used to provide a further understanding of the present disclosure and constitute a part of the present disclosure. The exemplary embodiments and descriptions of the present disclosure are used to illustrate the present disclosure and do not limit the present disclosure, in which:

FIG. 1 is a schematic diagram of a cabinet and a heat dissipation door thereof according to an embodiment of the present disclosure.

FIG. 2 is an exploded view of a heat dissipation door according to an embodiment of the present disclosure.

FIG. 3 is a schematic diagram of a fluid path according to an embodiment of the present disclosure.

### DETAILED DESCRIPTION OF THE EMBODIMENTS

In order to make the objectives, technical solutions, and advantages of the present disclosure clearer, the technical solutions of the present disclosure will be described clearly and completely in conjunction with specific embodiments and the figures of the present disclosure. Significant ly, the described embodiments are only a part of the embodiments of the present disclosure, rather than all the embodiments. Based on the embodiments in the present disclosure, all other embodiments obtained by a person of ordinary skill in the art without creative work fall within the protection scope of this disclosure.

The following description is of the best-contemplated mode of carrying out the present disclosure. This description is made for the purpose of illustrating the general principles of the present disclosure and should not be taken in a limiting sense. The scope of the present disclosure is best determined by reference to the appended claims.

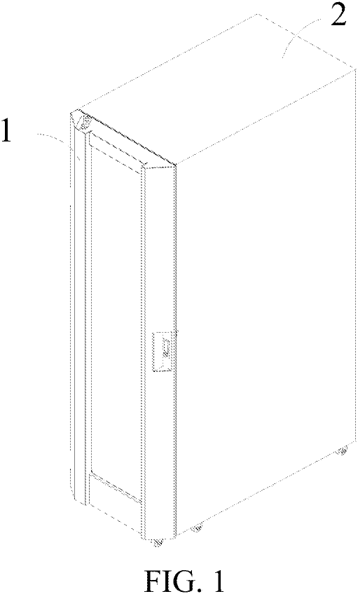

FIG. 1 is a schematic diagram of a cabinet and a heat dissipation door thereof according to an embodiment of the present disclosure. As shown in the figure, a cabinet includes a heat dissipation door 1 and a cabinet body 2, and the heat dissipation door 1 is disposed on the cabinet body 2. In the present disclosure, the term “cabinet” refers to a carrier device in which a server is disposed. For example, the cabinet may be a server carrier device located in a computer room, and the server may include components such as a central processing unit, a graphics processing unit, a hard disk, a power supply, and a memory, but the present disclosure is not limited thereto. However, the present disclosure is not limited to the location of the cabinet. By disposing the heat dissipation door 1 on the cabinet body 2, the heat dissipation components in the heat dissipation door 1 may effectively take away the heat outside the heat dissipation door 1. Therefore, the cabinet body 2 may maintain a stable working temperature. In order to make the technical features of the present disclosure clear and easy to understand, the operation of heat dissipation door 1 and the details of each element in heat dissipation door 1 will be explained in detail hereinafter.

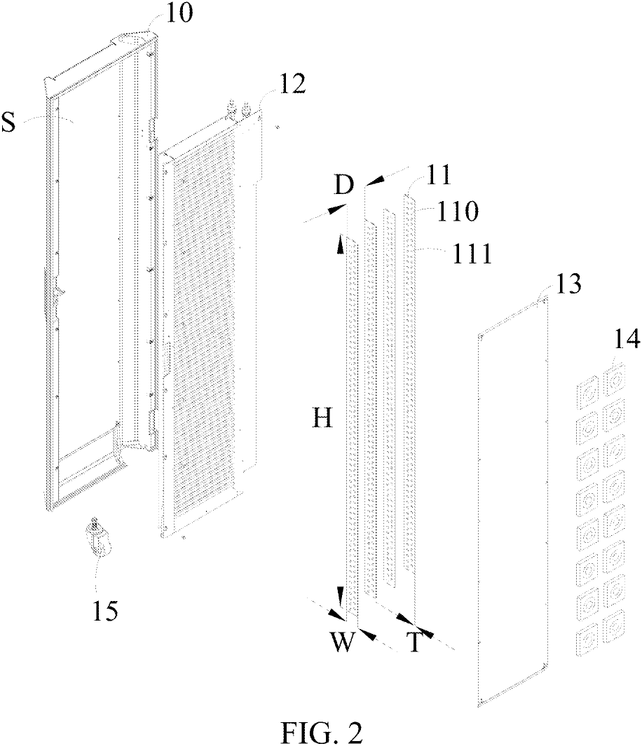

FIG. 2 is an exploded view of a heat dissipation door of an embodiment according to the present disclosure. As shown in the figure, the heat dissipation door 1 includes first plate 10, a plurality of heat dissipation sheets 11, and a heat dissipation tube component 12. In some embodiments, the first plate 10 may be a flat door plate on which the plurality of heat dissipation sheets 11 and the heat dissipation tube component 12 are disposed. However, the present disclosure is not limited thereto. In some embodiments, the first plate 10 may also have an accommodating space S, and the plurality of heat dissipation sheets 11, the heat dissipation tube component 12, and other components mentioned hereinafter are disposed in the accommodating space S.

In some embodiments, the heat dissipation door 1 may also include a second plate 13, and the second plate 13 is between the cabinet body 2 and the first plate 10 (as shown in FIG. 1). An accommodating space S is formed between the second plate 13 and the first plate 10, and the heat dissipation tube component 12 and the plurality of heat dissipation sheets 11 are in the accommodating space S. By covering the heat dissipation tube component 12 and the plurality of heat dissipation sheets 11 with the first plate 10 and the second plate 13, these heat dissipation components may be effectively protected to prolong the service life of the device.

It should be noted that the heat dissipation door 1 of the present disclosure is composed of a door plate (eg, the heat dissipation sheets 11 and the heat dissipation tube component 12, etc.) and the heat dissipation components therein, and the door plate is used for carrying heat dissipation components. Therefore, any door plates (eg, the first plate 10 or the combination of the first plate 10 and the second plate 13 mentioned above) well known to a person having ordinary skill in the art may be used in the present disclosure. In the following, the heat dissipation door 1 including the first plate 10 and the second plate 13 will be used as an example for illustration, but the present disclosure is not limited thereto.

The plurality of heat dissipation sheets 11 are provided on a side of the first plate 10 adjacent to the cabinet body 2, and each of the plurality of heat dissipation sheets 11 has a dissipation surface 110. More specifically, each heat dissipation sheet 11 has two dissipation surfaces 110 corresponding to each other, and the distance between the two dissipation surfaces 110 is a thickness T of the heat dissipation sheet 11. Wherein, the thickness T of the heat dissipation sheets 11 may be determined according to the actual use requirements. When the thickness T of the heat dissipation sheets 11 is larger, the heat capacity of the heat dissipation sheets 11 increases and the heat dissipation effect may be improved. Conversely, when the thickness T of the heat dissipation sheets 11 is smaller, the volume occupied by the heat dissipation sheets 11 decreases, so that more heat dissipation sheets 11 may be accommodated in the first plate 10.

In some embodiments, the length of each heat dissipation sheet 11 in a vertical direction is a height H of the heat dissipation sheet 11. Wherein, the height H of the heat dissipation sheets 11 may be determined according to the actual use requirements. When the height H of the heat dissipation sheets 11 is larger, the heat capacity of the heat dissipation sheets 11 increases and the heat dissipation effect may be improved. It should be noted that the height H of the heat dissipation sheets 11 is preferably less than or equal to the length of the first plate 10 in the vertical direction to prevent the heat dissipation sheets 11 from exposing from the first plate 10.

In some embodiments, the length of each heat dissipation sheet 11 in a direction away from the first plate 10 is a width W of the heat dissipation sheet 11. Wherein, the width W of the heat dissipation sheets 11 may be determined according to the actual use requirements. When the width W of the heat dissipation sheets 11 is larger, the heat capacity of the heat dissipation sheets 11 increases and the heat dissipation effect may be improved. It should be noted that, when the heat dissipation door 1 has both the first plate 10 and the second plate 13, the width W of the heat dissipation sheets 11 is less than or equal to the distance between the inner surface of the first plate 10 (the surface away from the external environment) and the inner surface of the second plate 13 (the surface away from the cabinet body 2).

In some embodiments, the plurality of heat dissipation sheets 11 are orthogonal to the inner surface of the first plate 10 and are sequentially disposed on the first plate 10 along a horizontal direction. In addition, the plurality of heat dissipation sheets 11 may also be orthogonal to the ground. It should be noted that the term “orthogonal” as used in the present disclosure refers to two elements (eg, the plurality of heat dissipation sheets 11 and the first plate 10) being substantially perpendicular to each other, which includes unexpected situations such as slight angles (eg, 0.1 degrees to 5 degrees) between the two elements due to tolerances or assembly processes.

In some embodiments, the plurality of heat dissipation sheets 11 may have a specific angle other than 0 degrees between the inner surface of the first plate 10, and/or the plurality of heat dissipation sheets 11 may be disposed on the first plate 10 in sequence along a specific direction other than the horizontal direction. By disposing the plurality of heat dissipation sheets 11 with the specific angles and/or the specific directions, the heat dissipation door 1 of the present disclosure may have more diverse configurations to be applied to cabinet bodies 2 of different types, shapes, and sizes, and the same excellent heat dissipation effect may be also achieved. It should be noted that the plurality of heat dissipation sheets 11 may have two or more than two specific angles or two or more than two specific directions at the same time. The present disclosure should not be limited to one specific angle or one specific direction.

In some embodiments, a specific separation distance D may be between two adjacent heat dissipation sheets 11. Wherein, the separation distance D between two adjacent heat dissipation sheets 11 (regarded as one group) may be the same or different from the separation distance D of another group. In the present disclosure, the term “separation distance D” refers to the distance between one side surface of the heat dissipation sheets 11 and the side surface of the adjacent heat dissipation sheets 11 on the same side. For example, the separation distance D between two adjacent heat dissipation sheets 11 in each group may be the first length. By disposing the separation distances D to be the same, the cabinet body 2 may be prevented from having a significant temperature gradient in the horizontal direction. However, the present disclosure is not limited thereto. In other embodiments, when more central processing units (CPU) are stacked in the central area of the cabinet body 2, the separation distance D between adjacent two heat dissipation sheets 11 in each group of the present disclosure may be the first a length or a second length. Wherein, the first length is smaller than the second length. Further, the separation distance D between the two adjacent heat dissipation sheets 11 located in the central area of the first plate 10 is the first length, and the separation distance D between the two adjacent heat dissipation sheets 11 located in the peripheral area of the first plate 10 is the second length. As a result, the heat dissipation effect of the central area of the first plate 10 may be effectively enhanced by disposing the heat dissipation sheets 11 with higher density in the central area.

In some embodiments, the plurality of heat dissipation sheets 11 may be fixed on the inner surface of the first plate 10 by adhering, fitting, locking, etc., which are well known to a person having ordinary skills in the art. For example, the inner surface of the first plate 10 may be concave with a plurality of engaging grooves, and the thickness of the engaging grooves may be similar to the thickness T of the heat dissipation sheets 11 (for example, may be the same or slightly smaller). The heat dissipation sheets 11 may be stably fixed on the first plate 10 by clamping or interference fit. It should be noted that the methods mentioned above are only examples, and the present disclosure may also adopt other fixing methods, or combine the two fixing methods to obtain a more excellent fixing effect.

In some embodiments, when the heat dissipation door 1 has the first plate 10 and the second plate 13 at the same time, the plurality of heat dissipation sheets 11 may be fixed to the first plate 10 and the second plate 13 at the same time by the methods mentioned above or other suitable methods to obtain an excellent fixation. For example, the plurality of heat dissipation sheets 11 may be connected to the first plate 10 and the second plate 13 by clipping at the same time. Alternatively, the plurality of heat dissipation sheets 11 may be connected to the first plate 10 by clipping and connected to the second plate 13 by adhering.

In some embodiments, the plurality of heat dissipation sheets 11 may be provided with a thermally conductive coating. For example, the dissipation surface 110 of the plurality of heat dissipation sheets 11 may be provided with pure metals, alloys, ceramics, composite materials containing the materials mentioned above, or other suitable materials with good thermal conductivity by electroplating, sputtering, evaporation, coating, etc. to further improve the thermal conductivity of the plurality of heat dissipation sheets 11.

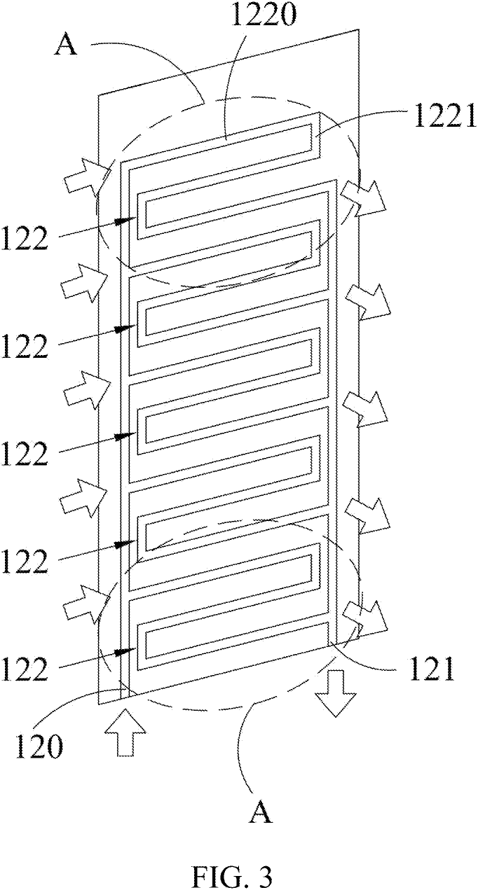

As shown in FIG. 2 and FIG. 3, wherein FIG. 3 is a schematic diagram of a fluid path according to an embodiment of the present disclosure. The heat dissipation tube component 12 is disposed on the side of the first plate 10 adjacent to the cabinet body 2, and the heat dissipation tube component 12 includes a water inlet 120, a water outlet 121, and a plurality of heat dissipation tubes 122. One end of the water inlet 120 is in fluid communication with a heat dissipation system. One end of the water outlet 121 is in fluid communication with the heat dissipation system. In the present disclosure, the heat dissipation system may be a cooling system of a building (eg, a cooling water tower) or a Cooling Distribution Unit (CDU), which is used to drive the heat transfer fluid in the heat dissipation tube component 12 circulating flow. However, the present disclosure is not limited to the devices mentioned above, and any cooling device or cooling system well known to a person having ordinary skills in the art may be applied in the present disclosure.

In the present disclosure, the positions of the water outlet 121 and the water inlet 120 may be determined according to the position of the heat dissipation door 1. In order to reduce the length/volume of connecting pipelines of the heat dissipation system, the water outlet 121 and the water inlet 120 are preferably disposed on the side of the heat dissipation door 1 adjacent to the ceiling or the ground, so that the connecting pipelines of the heat dissipation system disposed on the ceiling or the ground may be as close as possible to water outlet 121 and water inlet 120.

In some embodiments, the water outlet 121 and the water inlet 120 are on the side of the first plate 10 adjacent to the ground. More specifically, openings of water outlet 121 and water inlet 120 may be orthogonal to the ground. By disposing the water outlet 121 and the water inlet 120 adjacent to the ground and orthogonal to the ground, the total length of the connecting pipelines connected to the heat dissipation tube component 12 may be effectively reduced. Based on the configuration mentioned above, the present disclosure may further improve the space utilization of the entire device.

In some embodiments, the water outlet 121 and the water inlet 120 are on the side of the first plate 10 away from the ground. More specifically, the openings of the water outlet 121 and the water inlet 120 may be adjacent to the ceiling of the machine room, so that the connecting pipelines connected to the heat dissipation tube component 12 extend from the ceiling to the heat dissipation system.

Two ends of each of the plurality of heat dissipation tubes 122 respectively are in fluid communication with the water inlet 120 and the water outlet 121, and each of the plurality of heat dissipation tubes 122 has a plurality of extending sections 1220 and at least one connecting section 1220. The plurality of extending sections 1220 pass through the plurality of dissipation surfaces 110 in sequence, and at least one connecting section 1220 is connected to ends on the same side of adjacent two of the plurality of extending sections 1220. More specifically, the number of the plurality of extending sections 1220 may be N, and the number of connecting sections 1221 may be N-1. For example, the number of extending sections 1220 may be three, and the number of connecting sections 1221 may be two. Alternatively, the number of the plurality of extending sections 1220 may be five, and the number of the connecting sections 1221 may be four. It should be noted that two ends of each extending section 1220 are respectively connected to one of the connecting section 1221, the water inlet 120, and the water outlet 121, so that the entire heat dissipation tube 122 has only one flow path.

In some embodiments, the heat transfer fluid flowing in the heat dissipation tube component 12 may be water, an aqueous glycol solution, or a compatible cooling fluid. Preferably, the heat transfer fluid may be deionized water added with anticorrosion inhibitors and bactericides, which may avoid reducing the heat dissipation capacity and reliability due to corrosion, scaling, and microbial growth of the pipeline. Still more preferably, the heat transfer fluid is deionized water that may satisfy the following conditions:

| | | |
|---|---|---|
| Conductivity <1 uS /cm | Aluminum <0.05 mg/L | Potassium <0.01 mg/L |
| pH 6-8 | Antimony <0.1 mg/L | Magnesium <0.01 mg/L |
| Evaporation residue <10 mg/L | Arsenic <0.1 mg/L | Manganese <0.01 mg/L |
| Turbidity <=1.0 NTU | Boron <0.05 mg/L | Molybdenum <0.01 mg/L |
| Chloride such as chlorine <1.0 mg/L | Barium <0.01 mg/L | Sodium <0.02 mg/L |
| Sulfates such as calcium carbonate <0.5 mg/L | Calcium <0.01 mg/L | Nickel <0.01 mg/L |
| Heavy metal (Lead) <0.1 ppm | Cadmium <0.01 mg/L | Tin <0.1 mg/L |
| Silica <0.01 ppm | Chromium <0.01 mg/L | Zinc <0.01 mg/L |
| Nitrate <0.5 mg/L | Copper <0.01 mg/L | |
| Nitrite <0.5 mg/L | Iron <0.01 mg/L | |

In some embodiments, the temperature of the heat transfer fluid is within 10° C. to 45° C., which needs to be above the environment dew point. For example, the temperature of the heat transfer fluid may be 10° C., 15° C., 20° C., 25° C., 30° C., 35° C., 40° C., 45° C., or a value between the values mentioned above. In practical applications, the temperature of the heat transfer fluid may be adjusted according to the environment temperature, the condition of the central processing unit (CPU), and/or the characteristics of the heat transfer fluid.

In some embodiments, the dissipation surface 110 is orthogonal to the plurality of extending sections 1220. In other words, an angle of 90 degrees is formed between the plurality of extending sections 1220 and the dissipation surface 110. However, the present disclosure is not limited thereto. In other embodiments, a specific angle other than 90 degrees may be formed between the plurality of extending sections 1220 and the dissipation surface 110.

In some embodiments, the plurality of heat dissipation sheets 11 are in direct contact with the plurality of heat dissipation tubes 122. In the case where the plurality of heat dissipation sheets 11 and the plurality of heat dissipation tubes 122 are in contact with each other, the rate of heat conduction may be higher. In some embodiments, each heat dissipation sheet 11 may be provided with a plurality of passing holes 111 in advance, and each passing hole 111 corresponds to an extending section 1220 of the heat dissipation tubes 122. Furthermore, peripheral edges of the passing holes 111 and the extending section 1220 are in contact with each other, and a contact area between the heat dissipation sheets 11 and the extending sections 1220 is proportional to the thickness T of the heat dissipation sheets 11 (ie, the thickness of the peripheral edge). Therefore, by increasing the thickness T of the heat dissipation sheets 11 to increase the area of the periphery of the passing holes 111 in contact with the extending sections 1220, the heat conduction rate may be increased more effectively.

In some embodiments, the plurality of heat dissipation tubes 122 are disposed on the first plate 10 along the vertical direction in sequence. By disposing the plurality of heat dissipation tubes 122 in sequence, the heat dissipation door 1 may be divided into a plurality of heat dissipation sections A. When more heat dissipation sections A are formed, the temperature of the entire heat dissipation door 1 shows frequent periodic changes. For example, a low temperature (the extending section 1220 of the first heat dissipation tube 122 close to the water inlet 120), a medium temperature (the extending section 1220 of the first heat dissipation tubes 122 close to the water outlet 121), a low temperature (the extending section 1220 of the first heat dissipation tube 122 close to the water outlet 121), and a medium temperature (the extending section 1220 of the first heat dissipation tubes 122 close to the water outlet 121 are shown. In contrast, a significant temperature gradient is generated by the heat dissipation door with only one heat dissipation section A in the prior art. For example, a low temperature (the extending section 1220 of the heat dissipation tube 122 closest to water inlet 120), a medium temperature (the extending section 1220 of the heat dissipation tube 122 secondary close to the water inlet 120), a high temperature (the extending section 1220 of heat dissipation tube 122 secondary close to the water outlet 121) and ultra-high temperature (the extending section 1220 of the heat dissipation tube 122 closest to the water outlet 121) are shown. In contrast, the heat dissipation door 1 of the present disclosure with multiple heat dissipation sections A may effectively reduce the significant temperature gradient.

In some embodiments, the heat dissipation door 1 further includes a plurality of fans 14. The plurality of fans 14 is disposed between the heat dissipation sheets 11 and the cabinet body 2 and corresponds to the plurality of heat dissipation sheets 11. That is, the plurality of fans 14 may be provided inside the cabinet. Specifically, the fans 14 are configured to draw hot gas inside the cabinet body 2 to the outside of the heat dissipation door 1. As a result, the hot gas in the cabinet is cooled when passing through the heat dissipation tubes 122 and the heat dissipation sheets 11. Therefore, the hot gas becomes cool gas and leaves the heat dissipation door 1 in a low-temperature state. Furthermore, gas outside the heat dissipation door 1 is pushed to move away from the heat dissipation door 1. In addition, when the gas in the cabinet leaves the heat dissipation door 1 and moves in a direction away from the heat dissipation door 1, gas in the external environment may enter the cabinet body 2 from the side of the cabinet body 2 away from the heat dissipation door 1. A good heat dissipation cycle is formed.

In some embodiments, the plurality of fans 14 are disposed on the outer side of the first plate 10 and corresponds to the plurality of heat dissipation sheets 11. That is, the plurality of fans 14 may also be attached to the cabinet. In other embodiments, the plurality of fans 14 may also be disposed between the heat dissipation sheets 11 and the cabinet body 2 and outside the first plate 10 at the same time, so as to obtain a better suction effect. The operation of the plurality of fans 14 is similar or the same as that described above, and the description is omitted.

In some embodiments, when the heat dissipation door 1 further includes the plurality of fans 14, the first plate 10 and the second plate 13 respectively have a plurality of air holes. By disposing the air holes, the hot gas in the cabinet is easier to be driven by the fans 14 and leave the cabinet through the heat dissipation door 1. In some embodiments, in order to improve the stability of the air intake, the plurality of air holes are spaced apart from each other by a fixed distance. In some embodiments, in order to improve the local heat dissipation effect, the plurality of air holes are spaced apart from each other at different distances. For example, the area that needs to improve the heat dissipation effect may have more air holes correspondingly.

In some embodiments, the heat dissipation door 1 of the cabinet further includes a roller 15, and the roller 15 is disposed on the side of the first plate 10 adjacent to the ground. Since a large number of heat dissipation components such as heat dissipation tubes 122 and heat dissipation sheets 11 are provided in the heat dissipation door 1 of the present disclosure, the door must have a certain weight. Therefore, by providing the roller 15, the heat dissipation door 1 of the present disclosure may be easily opened or closed. It should be noted that, although one roller 15 is illustrated in the figure of the present disclosure, the present disclosure is not limited thereto. In other embodiments, the number of rollers 15 may be two, three, or more than three, which may be determined according to actual usage.

In summary, by passing the heat dissipation tubes of the heat dissipation tube component through the plurality of heat dissipation sheets in sequence, the present disclosure changes the heat dissipation path from the existing “central processing unit (CPU) is directly connected to the heat dissipation tubes” to “the central processing unit (CPU) is connected to the heat dissipation tubes through the plurality of heat dissipation sheets.” As a result, the heat dissipation area may be greatly increased by the plurality of heat dissipation sheets, thereby obtaining an excellent heat dissipation effect. In addition, due to the provision of the plurality of heat dissipation tubes, the entire heat dissipation door may be divided into a plurality of sections performing heat exchange with the corresponding central processing unit (CPU). As a result, the problem that the one path cold water pipeline in the prior art has a significant temperature gradient is also solved. Based on the configuration mentioned above, a heat dissipation door of cabinet with an excellent heat dissipation effect and no significant temperature gradient is realized by the present disclosure.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the invention. Accordingly, such modifications are considered within the scope of the invention as limited solely by the appended claims.

What is claimed is:

1. A heat dissipation door of cabinet, wherein the heat dissipation door is disposed on a cabinet body and comprises:
a first plate,
a plurality of heat dissipation sheets disposed on one side of the first plate adjacent to the cabinet body, wherein each of the plurality of heat dissipation sheets has a heat dissipation surface; and
a heat dissipation tube component disposed on one side of the first plate adjacent to the cabinet body and comprising:
a water inlet, wherein one end of the water inlet is in fluid communication with a heat dissipation system;
a water outlet, wherein one end of the water outlet is in fluid communication with the heat dissipation system; and
a plurality of heat dissipation tubes, wherein two ends of each of the plurality of heat dissipation tubes respectively are in fluid communication with the water inlet and the water outlet, each of the plurality of heat dissipation tubes has a plurality of extending sections and at least one connecting section, the plurality of extending sections passes through the heat dissipation surfaces in sequence, and at least one connecting section is connected to ends on the same side of two adjacent extending sections.

2. The heat dissipation door of cabinet of claim 1, the dissipation surfaces are orthogonal to the plurality of extending sections.

3. The heat dissipation door of cabinet of claim 1, the plurality of heat dissipation sheets are in direct contact with the plurality of heat dissipation tubes.

4. The heat dissipation door of cabinet of claim 1, the plurality of heat dissipation tubes are sequentially disposed on the first plate in a vertical direction.

5. The heat dissipation door of cabinet of claim 1, the water outlet and the water inlet are on a side of the first plate adjacent to a ground or on a side away from the ground.

6. The heat dissipation door of cabinet of claim 1, further comprising a plurality of fans disposed between the plurality of heat dissipation sheets and the cabinet body or outside the first plate, and the plurality of fans correspond to the plurality of heat dissipation sheets.

7. The heat dissipation door of cabinet of claim 1, further comprising a roller, wherein the roller is disposed on a side of the first plate adjacent to a ground.

8. The heat dissipation door of cabinet of claim 1, further comprising a second plate body, wherein the second plate body is between the cabinet body and the first plate, an accommodating space is formed between the second plate body and the first plate, and the plurality of heat dissipation tubes and the plurality of heat dissipation sheets are in the accommodating space.

9. The heat dissipation door of cabinet of claim 8, wherein the first plate and the second plate respectively have a plurality of air holes.

10. A cabinet, comprising:
a cabinet body; and
the heat dissipation door according to claim 1, wherein the heat dissipation door is disposed on the cabinet body.
